(19) United States
(12) Patent Application Publication
(10) Pub. No.: US 2004/0169240 A1
(43) Pub. Date: Sep. 2, 2004

(54) Semiconductor device and method of manufacturing semiconductor device

(76) Inventors: Masato Koyama, Miura-gun (JP); Akira Nishiyama, Yokohama-shi (JP); Yasushi Nakasaki, Yokohama-shi (JP); Masamichi Suzuki, Yokohama-shi (JP); Yuuichi Kamimuta, Kawasaki-shi (JP); Akio Kaneko, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/726,606

(22) Filed: Dec. 4, 2003

(30) Foreign Application Priority Data
Dec. 5, 2002 (JP) 2002-353964

(51) Int. Cl. H01L 29/76

(52) U.S. Cl. 257/411

(57) ABSTRACT

A semiconductor device comprises a substrate and a MISFET including source-drain regions formed in the substrate and a gate electrode formed on the substrate with a gate insulating film interposed therebetween. The gate electrode is formed of a metal oxynitride film containing a metal-oxygen-nitrogen bond chain. Alternatively, the gate insulating film is formed of a nitrided metal silicate film containing at least one of a metal-oxygen-nitrogen bond chain and asilicon-oxygen-nitrogen bond chain.

### CROSS-REFERENCE TO RELATED APPLICATIONS

This application is based upon and claims the benefit of priority from the prior Japanese Patent Application No. 2002-353964, filed Dec. 5, 2002, the entire contents of which are incorporated herein by reference.

### BACKGROUND OF THE INVENTION

1. Field of the Invention

The present invention relates to a semiconductor device and a method of manufacturing a semiconductor device, particularly, to a semiconductor device having a MIS field effect transistor (MISFET).

2. Description of the Related Art

The gate insulating film in a CMOS (Complementary Metal-Oxide-Semiconductor) device of the sub-0.1 μm era is required to have a thickness not larger than 1.5 nm in its SiO₂ equivalent. However, if the thickness of a SiO₂ film used as a gate insulating film in the past is decreased to reach 1.5 nm, the direct tunnel current causes the SiO₂ film to exhibit a conductor-like behavior and, thus, the SiO₂ film fails to act as an insulating film. Since the marked deterioration in the insulating characteristics accompanying the prominent reduction in the thickness of the film leads to an increase in the power consumption, it is considered impossible to put SiO₂ to the practical use for forming a gate insulating film in the semiconductor device in the future.

Such being the situation, vigorous research is being made in an attempt to develop a so-called “high-κ-gate insulating film technology” for realizing a thin insulating film in its SiO₂ equivalent while suppressing the leakage current by utilizing a material having a relative dielectric constant higher than that of SiO₂ (a high-κ material) so as to increase the physical thickness of the insulating film. However, the particular high-κ gate material, which is a metal oxide, gives rise to a serious problem that the material tends to be crystallized by the heat treatment under high temperatures. If the gate insulating film is crystallized, various phenomena are generated such as an increase in the gate leakage current, an increase in the impurity diffusion and the deterioration of the relative dielectric constant. These phenomena lead directly to the deterioration of the electrical characteristics of the semiconductor device.

As a means for preventing the crystallization of the high-κ material film, it has been found effective to add nitrogen to the film. It has been clarified to date that the crystallization of the high-κ material film under high temperatures can be suppressed by adding nitrogen to the high-κ material such as Hf silicate, ZrO₂, HfO₂ or Ta₂O₅.

The nitrogen atoms contained in the HfO₂ film formed by the conventional method are present in a manner to form a bond with the Hf atoms alone, which are metal atoms. The particular situation is considered to bring about a problem as described in the following. Specifically, if the metal atoms constituting the high-s material are bonded to nitrogen atoms, the conductivity of the high-κ material film is increased without fail. Therefore, the metal-nitrogen bond within the metal oxide material film is expected to deteriorate markedly the insulating properties of the film. As a matter of fact, TiN and TaN are known well as conductive materials and used for forming a conductive film in an LSI.

Even if the presence of a conductive bond such as a metal-nitrogen bond is accepted in the nitrogen-added high-κ material film, what should be considered in the next stage is the thermal stability of the particular bond. In general, it is absolutely necessary for a post heat treatment to be applied to the high-κ material film under a relatively high temperature after the film formation. The post heat treatment referred to above is intended mainly to repair, for example, the lattice defect within the film and to remove the impurities from within the film. It should be noted that the metal-nitrogen bond is very weak against a heat treatment, particularly, the heat treatment carried out in the presence of oxygen. To be more specific, the nitrogen atoms present in the film in the form of metal-nitrogen bonds are released to the outside of the film if the film is subjected to a heat treatment. In the case of a nitrogen-added HfO₂ film, it is reported that substantially all the nitrogen atoms within the film are scattered to the outside of the film in the case where a heat treatment is applied to the film at 650° C., which is considered to be a relatively low temperature in the LSI process.

Where nitrogen is added to a metal silicate, the nitrogen atoms form bonds with Si atoms. Since SiN is an insulating material as widely known in this technical field, the presence of the silicon-nitrogen bond within the film gives rise to no particular problem in respect of the insulating properties.

However, the particular situation is acceptable in only the case where the ratio of the number of metal atoms to the number of silicon atoms is relatively small (low metal ratio). Suppose that, in the nitrided metal silicate, the nitrogen atoms form bonds with the silicon atoms alone, and that metal-nitrogen bonds are not present and metal-oxygen bonds alone are present. In this case, it is partially acceptable for the silicon atoms to form bonds with oxygen atoms in the case of a low metal ratio. Such being the situation, a silicon-oxygen-metal bridge is formed so as to construct a network constituting the film. On the other hand, when it comes to a high metal ratio, all the silicon atoms are allowed to form bonds with nitrogen atoms, resulting in failure to form the silicon-oxygen-metal bridge. It follows that the film fails to form a network. Since the particular structure is in a so-called “phase separated state”, i.e., the structure in which silicon nitride and a metal oxide are mixed with each other without any atomic bonds interposed therebetween, it is anticipated that the particular structure is easily crystallized in the subsequent high temperature process.

Although it is considered possible to ensure the silicon atoms that form bonds with oxygen atoms by lowering the nitrogen concentration, a prescribed amount of nitrogen is required for controlling the crystallization. Such being the situation, it is anticipated that there is no room for forming silicon-oxygen bonds under the condition of a high metal ratio. If the bond between a metal element and a nitrogen atom is accepted, it is possible to form a network by the bridge of silicon-nitrogen-metal. It should be noted, however, that the metal-nitrogen bonds markedly deteriorate the insulating properties of the film and, even if the deterioration of the insulating properties is accepted, the metal-nitrogen bonds are converted into metal-oxygen bonds after the heat treatment because the oxidation resistance of the metal-nitrogen bonds are very weak as already described.

Incidentally, it is reported that nitrogen bonds having a high binding energy are formed in addition to the NSi₃ component if a plasma nitriding treatment is applied to the metal silicate. The nitrogen under the particular bond state is annealed out by the heat treatment carried out after the nitrogen addition. To be more specific, the nitrogen bond state remaining within the film other than NSi₃ having a high thermal stability has not yet been obtained nowadays even after the heat treatment at 1,000° C.

As described above, in the conventional metal oxynitride film or the nitrided metal silicate film, the nitrogen atoms form bonds with metal atoms so as to be present in the form of metal-nitrogen bonds low in resistance to oxidation and having a high conductivity. In the case of the nitrided metal silicate film, it is possible for the nitrogen atoms to be present in the form other than the metal-nitrogen bonds. However, it was impossible to obtain such bonds in the composition region in which the concentration of the metal atoms is relatively high.

As described above, it is possible for the nitrogen-metal bonds that are formed by the nitrogen introduced into the high-κ material for suppressing the crystallization to markedly deteriorate the performance of the gate insulating film.

The present invention, which has been achieved in view of the problems described above, is intended to provide a semiconductor device including a MISFET type field effect transistor comprising a gate insulating film formed of a metal oxynitride film or a nitrided metal silicate film excellent in its insulating properties and capable of suppressing the crystallization even if a metal is contained therein in a high concentration and to provide a method of manufacturing the particular semiconductor device.

### BRIEF SUMMARY OF THE INVENTION

According to an aspect of the present invention, there is provided a semiconductor device, comprising: a substrate; and a MISFET including source-drain regions formed within the substrate and a gate electrode formed on the substrate with a gate insulating film interposed therebetween, the gate insulating film consisting of a metal oxynitride film containing a metal-oxygen-nitrogen bond chain.

According to other aspect of the present invention, there is provided a semiconductor device, comprising: a substrate; and a MISFET including source-drain regions formed within the substrate and a gate electrode formed on the substrate with a gate insulating film interposed therebetween, the gate insulating film consisting of a nitrided metal silicate film containing at least one of a metal-oxygen-nitrogen bond chain and a silicon-oxygen nitrogen bond chain.

According to other aspect of the present invention, there is provided a method of manufacturing a semiconductor device, comprising: forming a metal oxide film on a substrate; applying a heat treatment to the metal oxide film under temperature falling within a range of between 700° C. and 900° C.; adding nitrogen to the metal oxide film after the heat treatment by using nitrogen under an excited state so as to obtain a gate insulating film consisting of a metal oxynitride film containing a metal-oxygen-nitrogen bond chain; and forming a gate electrode on the gate insulating film.

According to other aspect of the present invention, there is provided a method of manufacturing a semiconductor device, comprising: forming a metal silicate film on a substrate; applying a heat treatment to the metal silicate film under temperature falling within a range of between 700° C. and 900° C.; adding nitrogen to the metal silicate film after the heat treatment by using nitrogen under an excited state so as to obtain a gate insulating film consisting of a nitrided metal silicate film containing at least one of a metal-oxygen-nitrogen bond chain and a silicon-oxygen-nitrogen bond chain; and forming a gate electrode on the gate insulating film.

According to other aspect of the present invention, there is provided a method of manufacturing a semiconductor device, comprising: forming by a CVD method on a substrate a gate insulating film consisting of a metal oxynitride film having a metal-oxygen-nitrogen bond chain, the CVD method being carried out in the presence of nitrogen under an excited state; and forming a gate electrode on the gate insulating film.

According to other aspect of the present invention, there is provided a method of manufacturing a semiconductor device, comprising: forming by a CVD method on a substrate a gate insulating film consisting of a nitrided metal silicate film having at least one of a metal-oxygen-nitrogen bond chain and a silicon-oxygen-nitrogen bond chain, the CVD method being carried out in the presence of nitrogen under an excited state; and forming a gate electrode on the gate insulating film.

According to other aspect of the present invention, there is provided a semiconductor device, comprising: a substrate; and a MISFET including source-drain regions formed in the substrate, a gate insulating film formed on the substrate, and a gate electrode formed on the gate insulating film , the gate insulating film comprising a metal oxynitride film, the metal oxynitride film consisting of metal, oxygen and nitrogen, and the metal oxynitride film having peaks of binding energy corresponding to a metal-oxygen bond and a oxygen-nitrogen bond.

According to other aspect of the present invention, there is provided a semiconductor device, comprising: a substrate; and a MISFET including source-drain regions formed in the substrate, a gate insulating film formed on the substrate, and a gate electrode formed on the gate insulating film, the gate insulating film comprising a nitride metal silicate film, the nitride metal silicate film consisting of metal, oxygen, nitrogen and silicon, and the nitride metal silicate film having peaks of binding energy corresponding to a oxygen-nitride bond and a silicon-nitrogen bond.

### BRIEF DESCRIPTION OF THE SEVERAL VIEWS OF THE DRAWING

FIG. 1 schematically shows the bond state of the elements constituting the gate insulating film included in a semiconductor device according to one embodiment of the present invention;

FIGS. 2A and 2B are graphs each showing the experimental data in respect of the annealing resistance of nitrogen contained in the gate insulating film included in the semiconductor device according to one embodiment of the present invention;

FIG. 3 schematically shows the bond state of the elements contained in the gate insulating film included in the conventional semiconductor device;

FIGS. 4A and 4B are graphs each showing the experimental data in respect of the annealing resistance of nitrogen contained in the gate insulating film included in the conventional semiconductor device;

FIG. 5 schematically shows the bond state of the elements constituting the gate insulating film included in a semiconductor device according to another embodiment of the present invention;

FIG. 6 is an XPS spectrum for a nitrided metal silicate;

FIG. 7 is a graph showing the result of an X-ray diffractometry, which denotes the influences given by the concentration of the nitrogen atoms contained in the gate insulating film;

FIG. 8 shows an XPS spectrum denoting the nitrogen bond state in a nitrided metal silicate; and

FIG. 9 is a cross sectional view schematically showing the construction of a MISFET according to one embodiment of the present invention.

### DETAILED DESCRIPTION OF THE INVENTION

Some embodiments of the present invention will now be described with reference to the accompanying drawings.

The gate insulating film included in the semiconductor device according to one embodiment of the present invention is formed of a metal oxynitride film or a nitrided metal silicate film each containing nitrogen atoms under a specified bond state. The nitrogen atom forms a bond with a metal atom with an oxygen atom interposed therebetween in the case of the metal oxynitride film, and forms a bond with a metal atom or a silicon atom with an oxygen atom interposed therebetween in the case of the nitrided metal silicate film.

The bond states of the nitrogen atom in the metal oxynitride film and in the nitrided metal silicate film will now be described, covering the case where Hf is contained as the metal in the gate insulating film.

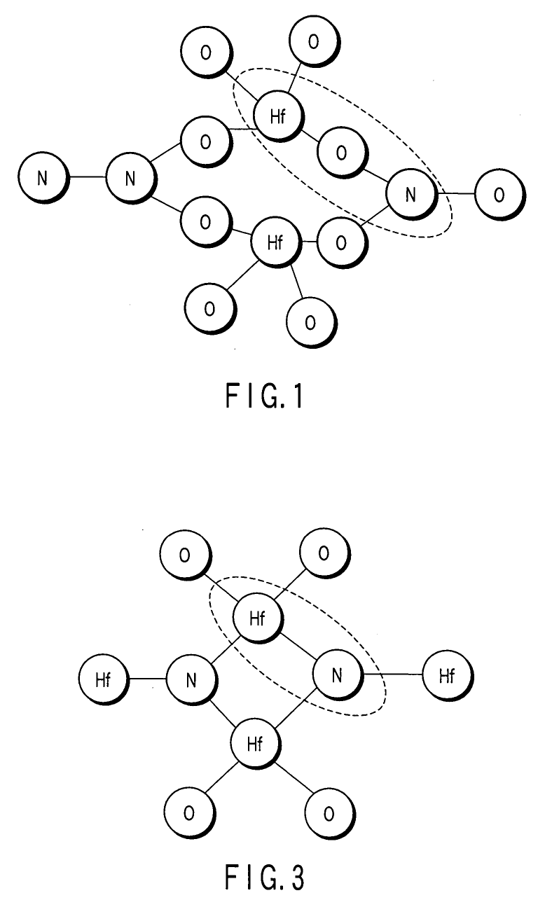

FIG. 1 schematically shows the bond state of the nitrogen atoms within a metal oxynitride film constituting the gate insulating film included in the semiconductor device according to one embodiment of the present invention. As shown in the drawing, the nitrogen atom does not form a bond directly with the Hf atom used as a metal atom, but forms a metal-oxygen-nitrogen bond chain with an oxygen atom interposed between the nitrogen atom and the Hf atom.

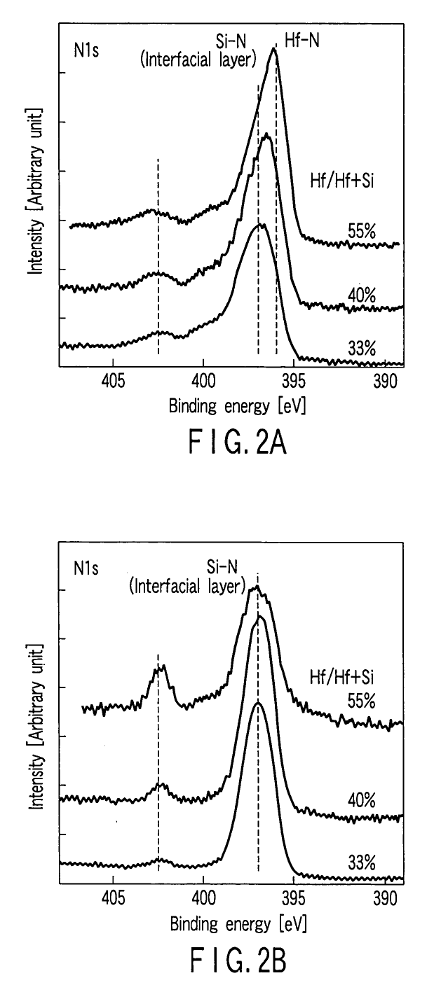

The nitrogen atom included in the metal-oxygen-nitrogen bond chain exhibits a drastically improved thermal stability, compared with the conventional metal-nitrogen bond. Each of FIGS. 2A and 2B shows the binding energy in a metal oxynitride film containing the particular bond chain. Specifically, FIG. 2A shows the binding energy immediately after deposition of the film, and FIG. 2B shows an N1s XPS spectrum after the heat treatment at 1,000° C. for 30 seconds, which is a typical heat treating step employed in the LSI process. The peak observed in the vicinity of 402 to 403 eV in FIG. 2B denotes the presence of the nitrogen-nitrogen bond and the nitrogen-oxygen bond. This clearly supports that the metal-oxygen-nitrogen bond remains inside the film even after the heat treatment at 1,000° C. The film also had a peak at a bonding energy corresponding to Hf—O bond.

FIG. 3 schematically shows the atomic bond state inside the conventional nitrogen-added HfO₂. This example corresponds to the nitrogen-added HfO₂ reported in “Appl. Phys. Lett. 81.2593 (2002)”. As shown in the drawing, the nitrogen atom within the film forms a bond with a Hf atom. It is known to the art that the Hf—N bond serves to suppress the crystallization of HfO₂ so as to improve the resistance of oxygen to diffusion.

However, the Hf—N bond is caused to disappear completely under a low temperature of about 650° C. so as to be replaced by a Hf—O bond. This supports that the Hf—N bond is weak against the heat treatment, indicating an disadvantage generated by the nitrogen addition under the particular state to a metal oxide.

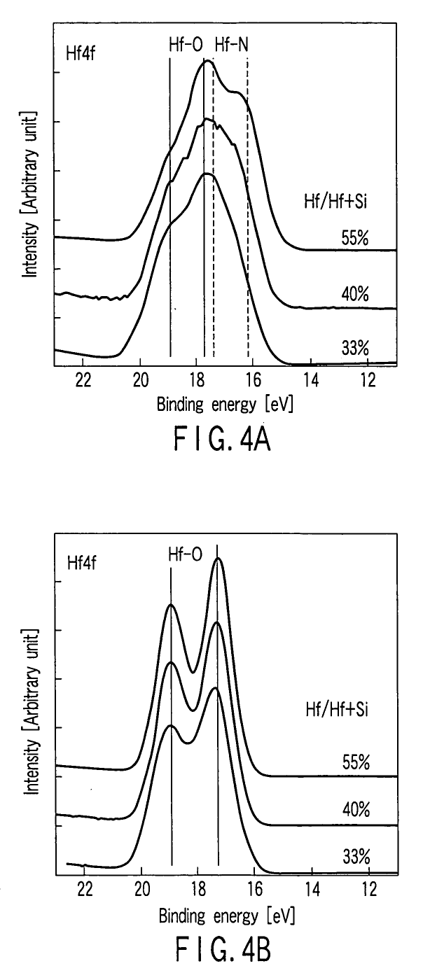

Each of FIGS. 4A and 4B shows an XPS spectrum indicating the brittleness relative to the heat treatment of the Hf—N bond characterizing the prior art. To be more specific, FIG. 4A covers the film immediately after the deposition, and FIG. 4B shows the binding energy of the film after the heat treatment at 1,000° C. for 30 seconds. As apparent from FIG. 4A, peaks of the Hf—O bond are observed at 17.5 eV and 19.0 eV. Also, peaks of the Hf—N bond are observed at 16.5 eV and 18.0 eV. It follows that the Hf—N bond and the Hf—O bond are present together in the film immediately after the deposition.

On the other hand, all the Hf—N bonds are caused to disappear completely by the heat treatment at 1,000° C. for 30 seconds so as to be replaced by the Hf—O bonds, as shown in FIG. 4B. Such being the situation, the nitrogen atom forming a bond with the hafnium atom is considered to have been scattered to the outside of the film. Since the nitrogen atom is scattered from within the film, the effect of suppressing the crystallization, which is produced by the nitrogen atom, is considered to lost completely.

The problem pointed out above is considered to be common with the use of metals such as Ti, Zr and a rare earth metal in addition to Hf.

Table 1 shows the change in the amount of each of the Hf—N bond and the Hf—O—N bond, which is caused by the annealing at 1,000° C.

TABLE 1

| | |
|---|---|
| Hf—N (prior art) | |
| (at %) | Hf—O—N (at %) |

| Hf/(Hf + Si) | as-depo. | 1000° C. | as-depo. | 1000° C. |
|---|---|---|---|---|
| 33% | 8.6 | 0 | 4.3 | 1 |
| 40% | 12.6 | 0 | 3.9 | 1.4 |
| 55% | 20.2 | 0 | 3.2 | 1.6 |

As shown in Table 1, the Hf—N bond was caused to disappear substantially completely by the annealing at 1,000° C.; whereas, the nitrogen atoms included in the Hf—O—N bonds exhibited the maximum remaining rate of about 50%. Since the nitrogen atom under the state of the Hf—O—N bond is present in the film even during the high temperature treating step, it is possible to improve drastically the effects of, for example, suppressing the crystallization of the film and improving the resistance to the diffusion of the impurities.

It has been confirmed that the binding energy of the N1s inner-shell electron included in the Hf—O—N bond is higher than the binding energy (NSi₃) of the N1s inner-shell electron within Si₃N₄, which is widely known to the art. The situation can be understood without difficulty, if attentions are paid to the phenomenon that the nitrogen atom is deprived of electrons by the oxygen. It is known to the art that the relative energy difference from NSi₃ is typically +2 eV or more, and is about +5 eV as a main component of the bond.

The nitrogen-added metal silicate will now be described, with a nitrogen-added Hf silicate taken up as an example. Theoretically, it is possible for four kinds of compounds, i.e., SiO₂, Si₃N₄, HfO₂ and HfN, to be present in the nitrogen-added Hf silicate. As already described, all the nitrogen atoms contained in the conventional nitrogen-added Hf silicate are present in the form of Si—N bonds. As widely known to the art, the Si—N bond exhibits a very high thermal stability. As a matter of fact, it has been demonstrated that the material containing the Si—N bonds is not decomposed even if a heat treatment is applied to the material under high temperatures of 1,000 ° C. or more. It follows that, in the conventional nitrogen-added Hf silicate, the nitrogen atoms contained in the silicate form bonds with Si atoms alone so as to form Si—N bonds. In other words, the Hf—N bond is not included in the conventional nitrogen-added Hf silicate.

In order to improve the thermal stability, it is necessary to increase the nitrogen concentration in the film. However, since the nitrogen atoms form bonds with Si atoms alone in the conventional nitrogen-added Hf silicate, the number of Si atoms forming bonds with oxygen atoms is decreased with increase in the nitrogen concentration. Suppose all the Si atoms form bonds with nitrogen atoms. In this case, the nitrogen-added Hf silicate is in the form of a mixture consisting of Si₃N₄ and HfO₂. What should be noted is that, since a bridging atom is not present between the Si atom and the Hf atom in this case, it is unavoidable in principle that the nitrogen-added Hf silicate material assumes the structure that the Si₃N₄ phase is separated from the HfO₂ phase. If the phase separation is generated, it is difficult to ensure the spatial uniformity that must be satisfied by the gate insulating film. Further, the detrimental effect such as the deterioration of the relative dielectric constant is rendered visible.

Within the composition range in which the nitrogen concentration and the metal concentration are low, there is room for the Si atom to form a bond with an oxygen atom even in the conventional nitrogen-added Hf silicate so as to make it possible to avoid the phase separation in the film. However, the composition range within which the phase separation can be avoided in the film is limited to a narrow range, leading to a disadvantage. Also, the phase separation can be prevented if the metal-nitrogen bond is accepted. In this case, however, the particular structure is low in its thermal stability, with the result that it is substantially impossible to maintain the presence of the metal-nitrogen bond within the film.

Such being the situation, a nitrided metal silicate containing at least one of the metal-oxygen-nitrogen bond chain and the silicon-oxygen-nitrogen bond chain is used for forming the gate insulating film included in a semiconductor device in another embodiment of the present invention so as to avoid the above-noted problems inherent in the prior art.

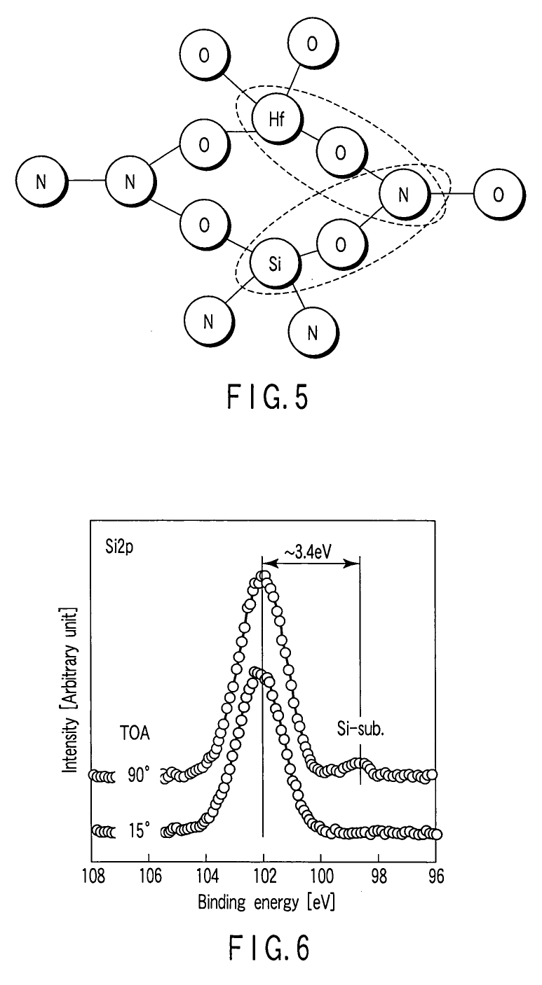

FIG. 5 schematically shows the bond state of the nitrogen atoms contained in the nitrided metal silicate constituting the gate insulating film of the semiconductor device according to the other embodiment of the present invention. As shown in the drawing, the nitrogen atom does not form a bond directly with a Si atom or a Hf atom used as a metal atom, but forms a silicon-oxygen-nitrogen bond chain or a metal-oxygen-nitrogen bond chain with an oxygen atom interposed between the nitrogen atom and the silicon atom or the metal atom.

Because of the particular bond chain, the present invention has made it possible to permit a sufficiently large amount of nitrogen to be present in the nitrided metal silicate film even if the metal-nitrogen bond or the silicon-nitrogen bond is not present in the film. As a result, the problem of the material phase separation can be resolved so as to make it possible to obtain the effect of improving the thermal stability of the material produced by the nitrogen addition within the composition range broader than that in the prior art.

Incidentally, even in the composition region of a low metal concentration within which the conventional nitrogen-added metal silicate is capable of maintaining its thermal stability, the metal-oxygen-nitrogen bond chain and/or the silicon-oxygen-nitrogen bond chain clearly holds a dominant position. In the conventional nitrogen-added metal silicate, nitrogen atoms are arranged in many free valences of the Si atom. As a result, the Si₃N₄-like substance region is increased so as to decrease relatively the SiO₂-region. In view of the insulating properties and the high reliability, it is clearly advantageous for the SiO₂-like region to occupy a larger region of the nitrogen-added metal silicate. In the nitrided metal silicate film containing the metal-oxygen-nitrogen bond chain and/or the silicon-oxygen-nitrogen bond chain, a high nitrogen concentration can be maintained in the film while arranging a larger number of oxygen atoms in the free valences of the Si atom. It follows that it is possible to improve the characteristics such as the insulating properties and the long-term reliability of the film.

FIG. 6 is a graph showing the Si2p XPS spectrum in the nitrided metal silicate film containing the silicon-oxygen-nitrogen bond chain. The graph covers the film immediately after the deposition. The fine peak observed in the vicinity of 98.5 eV represents the Si atom contained in the Si substrate, and the peak in the vicinity of 102 eV represents the presence of the Si atom contained in the nitrided metal silicate. Since the difference in the binding energy between these two peaks is about 3.4 eV, it has been confirmed that both a nitrogen atom and an oxygen atom are bonded to the Si atom contained in the nitrided metal silicate film.

It has also been confirmed that the binding energy of the N1s inner-shell electron included in the Si—O—N bond is higher than the binding energy of the N1s inner-shell electron within Si₃N₄ as in the Hf—O—N bond referred to previously. The particular situation can be understood if attentions are paid to the phenomenon that the nitrogen atom is deprived of electrons by the oxygen atom. It is known to the art that the relative energy difference from NSi₃ is typically +2 eV or more, and is about +5 eV as a main component of the bond.

If the temperature for the heat treatment in the LSI manufacturing process is lowered, it is possible to permit the metal-nitrogen bond, which is unsatisfactory in its thermal stability, to remain in the metal oxynitride film or the nitrided metal silicate film. However, as widely known to the art, substantially all the metal nitrides excluding, for example, aluminum nitride exhibit an electrical conductivity. Such being the situation, the metal nitride causes the dielectric resistance of the film to be markedly deteriorated substantially without fail. The present invention has made it possible to avoid the deterioration of the dielectric resistance caused by the metal-nitrogen bond by allowing the nitrided metal silicate film to contain the metal-oxygen-nitrogen bond chain and/or the silicon-oxygen-nitrogen bond chain.

Hafnium (Hf) is taken up as an example in the description given above. It is considered reasonable to understand that the similar effect can be obtained in respect of Ti or Zr, which is homologous to Hf. Also, substantially the same effect can be anticipated in the case of a metal oxynitride film or a nitrided metal silicate film containing a lanthanoide metal such as La, Ce, Pr, Nd, Pm, Sm, Eu, Gd, Tb, Dy, Ho, Er, Tm, Yb or Lu.

It is desirable for the concentration of nitrogen contained in a metal oxynitride film including a metal-oxygen-nitrogen bond chain or in a nitrided metal silicate film including a metal-oxygen-nitrogen bond chain and/or a silicon-oxygen-nitrogen bond chain to fall within a range of between 15 atomic % and 30 atomic %.

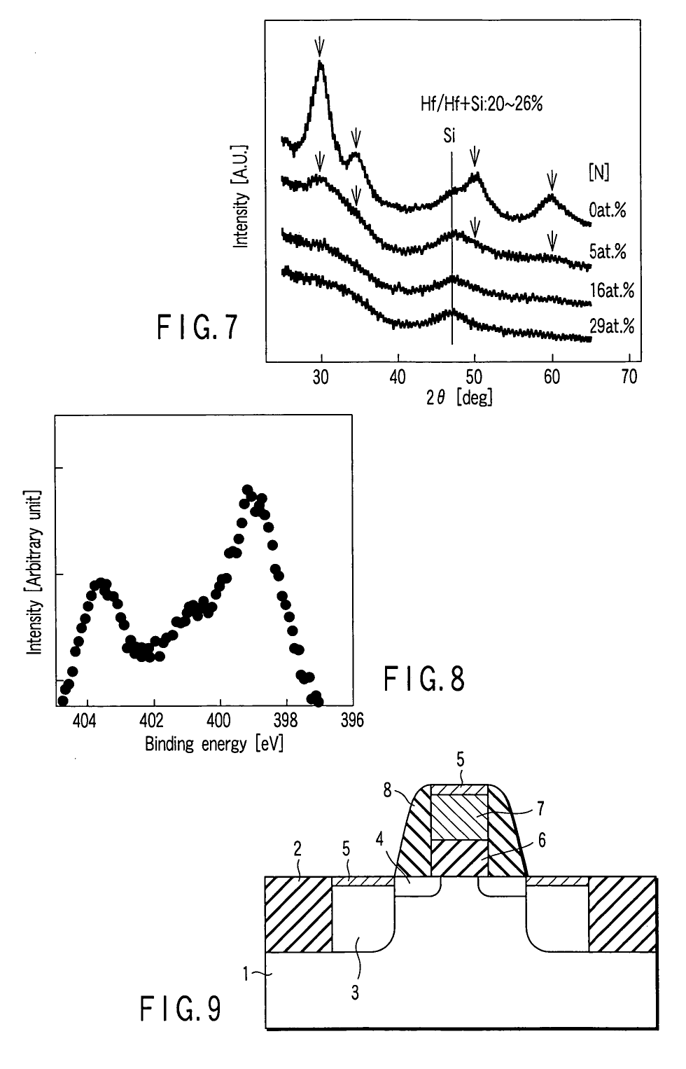

FIG. 7 is a graph showing the result of the X-ray diffraction experiment in which the thermal stability of a nitrogen-added Hf silicate film containing a metal-oxygen-nitrogen bond chain and/or a silicon-oxygen-nitrogen bond chain was tested at 1,000° C. FIG. 7 also shows the result for the Hf silicate film having a nitrogen concentration of 0 atomic %. In this case, the four peaks appearing at 30 deg, 35 deg, 50 deg and 60 deg support that a large amount of crystalline components are contained in the silicate film. The graph of FIG. 7 shows that, if the nitrogen content is lowered to 5 atomic %, traces of crystalline components are contained in the film, though the crystallization of the film can be markedly suppressed. On the other hand, where the nitrogen content was increased to 16 atomic % or 29 atomic %, a crystal was not detected at all in the film. The experimental data support that, in order to permit the effect of suppressing the crystallization to be exhibited sufficiently, it is desirable for the nitrogen concentration to be at least 15 atomic % in the nitrogen-added metal silicate film containing a metal-oxygen-nitrogen bond chain and/or a silicon-oxygen-nitrogen bond chain.

On the other hand, where the nitrogen concentration exceeds 30 atomic %, the electrical insulating properties were somewhat lowered or very small strains are generated in the film. In order to suppress the crystallization of the film without giving rise to any inconvenience, it is desirable for the nitrogen concentration to fall within a range of between 15 atomic % and 30 atomic %.

The metal oxynitride film or the nitrided metal silicate film exhibiting the characteristics described above can be obtained by, for example, applying a heat treatment at 700° C. to 900° C. to a metal oxide film or a metal silicate film, followed by adding nitrogen by using nitrogen under an excited state.

FIG. 8 is a graph showing the XPS spectrum for analyzing the bond state of nitrogen in the nitrogen-added Hf silicate film obtained by exposing nitrogen under an excited state to the Hf silicate film. The peak in the vicinity of 403 to 404 eV denotes nitrogen-oxygen bond, where the presence of nitrogen containing as a main component the metal-oxygen-nitrogen bond chain or the silicon-oxygen-nitrogen bond chain formed by the method described above. After deposition of the metal silicate film, a heat treatment was applied to the film at 700° C. to 900° C. for about 30 seconds to 30 minutes, followed by further applying a plasma nitrization treatment to the film. Because of the particular technology, the embodiment of the present invention has made it possible to permit the nitrogen atom to form a bond with a metal atom or a Si atom with an oxygen atom interposed therebetween.

Where the temperature for the heat treatment is lower than 700° C., the network structure of the metal silicate is rendered incomplete, and the metal-oxygen-nitrogen bond chain formed by exposing nitrogen under an excited state to the metal silicate film is also a part of the incomplete network structure. It follows that it is difficult for the film to withstand the subsequent heat treatment. On the other hand, where the temperature for the heat treatment exceeds 900° C., the metal silicate is separated into a metal oxide phase and a silicon oxide phase. It follows that, even if nitrogen under an excited state is exposed to the metal silicate film after the heat treatment, the film is converted into a spatially non-homogeneous nitrided metal silicate film, though the film contains a metal-oxygen-nitrogen bond chain and a silicon-oxygen-nitrogen bond chain. In any case, it is impossible to form a homogeneous nitrided metal silicate film containing a metal-oxygen-nitrogen bond chain and/or a silicon-oxygen-nitrogen bond chain each having a high thermal stability.

The peak in the vicinity of 399 eV in the XPS spectrum shown in FIG. 8 represents the presence of NSi₃ formed by the conventional method. The binding energy corresponding to NSi₃ shown in FIG. 8 is generated even in the case where the metal silicate film is exposed to nitrogen under an excited state without applying a heat treatment to the metal silicate film. However, since the particular bond represents the NSi₃ formed in the incomplete network structure, the bond is annealed out during the heat treatment carried out in the subsequent step.

The embodiment of the present invention has made it possible to form a metal-oxygen-nitrogen bond chain and/or a silicon-oxygen-nitrogen bond chain each having a sufficiently high thermal stability by applying a heat treatment to the film at 700° C. to 900° C. before the film is exposed to the excited nitrogen.

The metal silicate film can be deposited by an optional method such as a sputtering method, a CVD method, a MBE method, a vapor deposition method or a laser abrasion method. Particularly, it is desirable to deposit the metal silicate film by the CVD method because the CVD method permits improving the homogeneity of the silicate film and also permits suppressing the impurity elements to a low level.

It is also possible to form a metal oxynitride film having a metal-oxygen-nitrogen bond chain by employing the similar method. In this case, a metal oxide film deposited by an optional method is subjected to a heat treatment at 700° C. to 900° C. for about 30 seconds to 30 minutes, followed by exposing the metal oxide film after the heat treatment to nitrogen under an excited state.

Alternatively, a metal oxynitride film containing a metal-oxygen-nitrogen bond chain or a nitrided metal silicate film containing a metal-oxygen-nitrogen bond chain and/or a silicon-oxygen-nitrogen bond chain can be formed by a CVD method in the presence of an excited nitrogen.

To be more specific, a hafnium oxynitride film containing a metal-oxygen-nitrogen bond chain can be formed by a CVD method in the presence of nitrogen under an excited state in the step of forming a hafnium oxide film on a Si substrate under a substrate temperature of about 600° C. in a low pressure CVD apparatus using Hf(OC(CH₃)₃)₄ and an oxygen gas as raw materials. In the case of a nitrided metal silicate film, the film can be formed similarly by a CVD method in the presence of nitrogen under an excited state in the step of forming a hafnium silicate film on a Si substrate with the substrate temperature set at about 600° C. by using a low pressure CVD apparatus using Hf(OC(CH₃)₃)₄ and TEOS as raw materials.

When it comes to a film-forming method other than the CVD method, it is difficult to form a metal-oxygen-nitrogen bond chain and/or a silicon-oxygen-nitride bond chain within the film even if the deposition is carried out in the presence of an excited nitrogen. The embodiment of the present invention has made it possible to form the particular bond chain for the first time by employing the CVD method that is carried out in the presence of an excited nitrogen.

Incidentally, in the case of a metal silicate film, it is possible for a silicon-nitrogen-nitrogen-silicon bond chain to be formed. Although, the silicon-nitrogen-nitrogen-silicon bond chain cannot be formed by the conventional film-forming method, the present invention has made it possible to form the silicon-nitrogen-nitrogen-silicon bond chain by utilizing nitrogen under an excited state. The silicon-nitrogen-nitrogen-silicon bond chain, which has an additional nitrogen atom compared with the ordinary Si—N—Si bond chain, produces the function of increasing the nitrogen concentration within the nitrided metal silicate film, with the result that it is possible to increase the structural thermal stability of silicate.

The metal-oxygen-nitrogen bond chain within a metal oxynitride film or the metal-oxygen-nitrogen bond chain and/or the silicon-oxygen-nitrogen bond chain within the nitrided metal silicate film exhibits a thermal stability markedly higher than that of the metal-nitrogen bond. On the other hand, it is possible for a limited amount of the bond chain noted above to be destroyed so as to be scattered to the outside of the film. It is possible to apply an annealing treatment to the metal-oxygen-nitrogen bond chain and/or the silicon-oxygen-nitrogen bond chain after formation of the bond chain so as to restore the defect of the film, thereby increasing the living rate of the metal-oxygen-nitrogen bond and/or the silicon-oxygen-nitrogen bond chain.

For example, it is possible to avoid the oxidation by applying a heat treatment at 700° C. to 1,000° C. to the gate insulating film after the nitrogen addition under an atmosphere having an oxygen partial pressure of 1×10⁻³ Torr or less. Alternatively, it is also desirable to deposit the gate electrode without exposing the film to the air atmosphere after addition of nitrogen to the gate insulating film. Since the gate insulating film is covered with the gate electrode, it is possible to increase the rate of presence of the bond state of nitrogen by the high temperature heat treatment at 700° C. to 1,000° C.

Incidentally, Japanese Patent Disclosure No. 2002-314067 teaches a metal oxynitride film obtained by oxidizing a metal nitride film under a low temperature. The drawing included in this prior art indicates that the nitrogen within the film assumes the form of a metal-oxygen-nitrogen bond. However, an oxygen-oxygen bond is schematically denoted by a dotted line in the drawing, indicating that the particular structure is weak against the heat treatment. In this prior art, employed as the manufacturing method is a technology of oxidizing a metal nitride film under a low temperature, with the result that a metal-oxygen-nitrogen bond alone can be formed within the incomplete network structure as described previously. In the embodiment of the present invention, the particular problem inherent in the prior art has been solved by improving the manufacturing method.

As described above, according to the embodiment of the present invention, a metal-oxygen-nitrogen bond chain and/or a silicon-oxygen-nitrogen bond chain is present in a metal oxynitride film or a nitrided metal silicate film. It follows that the embodiment of the present invention makes it possible to maintain a high nitrogen concentration and, at the same time, to exclude the metal-nitrogen bond, which gives a detrimental effect to the performance of the gate insulating film, from the film.

A MISFET (Metal-Insulator-Semiconductor Field Effect Transistor) according to the embodiment of the present invention and a method of manufacturing the same will now be described with reference to the accompanying drawing. Needless to say, the present invention is not limited to the embodiment described below and can be modified in various fashions.

FIG. 9 is a cross sectional view schematically showing the construction of a semiconductor device according to one embodiment of the present invention.

In the semiconductor device shown in the drawing, a gate electrode 7 is formed on a substrate 1 with a gate insulating film 6 interposed therebetween. It is possible to use a substrate made of at least one of Si and Ge as the substrate 1. In the embodiment shown in the drawing, used was a silicon substrate. Source-drain diffusion regions 4 consisting of regions having an impurity diffused therein in a high concentration are formed in positions having the gate insulating film 6 sandwiched therebetween within the silicon substrate 1, thereby constructing a MOS transistor.

As already describe, the gate insulating film 6 is formed of a metal oxynitride film containing a metal-oxygen-nitrogen bond chain or a nitrided metal silicate film containing a metal-oxygen-nitrogen bond chain and/or a silicon-oxygen-nitrogen bond chain.

As an example, a nitrogen-added Hf silicate film is used as the gate insulating film 6 in the semiconductor device shown in FIG. 9.

In the first step, an element separating region 2 was formed by the ordinary method on the silicon substrate 1, followed by depositing the gate insulating film 6 over the entire wafer surface. In this case, a nitrogen-added Hf silicate film was formed by a CVD method in the presence of nitrogen under an excited state. To be more specific, the nitrogen-added Hf silicate film was formed by exposing nitrogen under an excited state, which was formed by a plasma discharge, to the inner region of a film-forming apparatus in the step of forming a Hf silicate on the Si substrate, with the substrate temperature maintained at 600° C., in a low pressure CVD apparatus using Hf(OC(CH₃)₃)₄, TEOS and an oxygen gas. In this step, it is possible to control the nitrogen concentration in the film by changing the supply rate of nitrogen under an excited state or the depositing rate of Hf silicate.

Also, it is possible to control the Hf/Si composition in the insulating film by changing the supply ratio of the Hf raw material and the Si raw material. In this case, the raw material supply ratio of HTB/TEOS/O₂ that permits the ratio of (Hf/Hf+Si) to be 50% was employed. In addition, the excited nitrogen was supplied in a manner to permit the nitrogen concentration within the film to be 20 atomic % so as to form a nitrogen-added Hf silicate film as the gate insulating film 6. The degree of vacuum within the apparatus was 1 Torr in the deposition stage.

Concerning the bond state of nitrogen in the nitrogen-added Hf silicate film thus obtained, the bonds having a binding energy higher than the binding energy of the N1s inner-shell electron within the Si₃N₄ film, which is known well in this technical field, were contained in a large amount in the resultant nitrogen-added Hf silicate film, as shown in FIGS. 2A and 2B. The nitrogen under the particular bond state is capable of withstanding the high temperature heat treatment at 1,000° C. as already described so as to markedly suppress the crystallization of the film and to improve the resistance to the diffusion of the impurities.

The embodiment described above is directed to a Hf silicate film. However, the present invention is effective when applied to the other metal silicate films such as a Zr silicate film, a Ti silicate film and a film of a rare earth element silicate in addition to the Hf silicate film. Also, the similar effect can be obtained when the technical idea of the present invention is applied to a metal oxynitride film that does not contain silicon.

After formation of the nitrogen-added Hf silicate film and the subsequent post heat treatment, the gate electrode 7 is deposited by the ordinary method. For example, the gate electrode 7 can be formed by the deposition of a polycrystalline silicon (poly-Si) or poly-SiGe by a low pressure CVD method or by the deposition of a metal nitride having a high boiling point such as TiN by the CVD method.

In the next step, after the gate electrode 7 and the gate insulating film 6 are processed by the ordinary method, formed are a shallow junction 4, a gate side wall 8 made of, for example, SiN, a deep junction 3, and a salicide films 5 so as to obtain the semiconductor device constructed as shown in FIG. 9.

In the semiconductor device thus obtained, the Hf—N bond that exhibits an electrical conductivity is not present at all within the gate insulating film, and the presence of a metal-oxygen-nitrogen bond chain and/or a silicon-oxygen-nitrogen bond were recognized. The Hf amount, i.e., Hf/(Si+Hf), in the nitrided metal silicate film was found to be high, i.e., about 50%, and the nitrogen concentration was found to be about 20 atomic %. Since nitrogen atoms were contained in the film in a sufficiently large amount, it was possible to suppress the crystallization of the nitrogen-added metal silicate film. In addition, since the Hf—N bond was not present in the gate insulating film 6, the film 6 was capable of maintaining high insulating properties.

As described above, according to the embodiment of the present invention, there is provided a semiconductor device including a MISFET type field effect transistor equipped with a gate insulating film formed of a metal oxynitride film or a nitrided metal silicate film excellent in the insulating properties and capable of suppressing the crystallization even if a metal is contained in the film in a high concentration. Also provided is a method of manufacturing the particular semiconductor device.

The present invention makes it possible to form a thermally stable high-κ insulating film having a metal concentration higher than that in the prior art so as to achieve a high performance in respect of, for example, the increase in the capacitance of the insulating film. The present invention, which greatly contributes to the practical use of the updated silicon CMOS device that can be operated at a high speed with a small power consumption, produces an amazing industrial value.

Additional advantages and modifications will readily occur to those skilled in the art. Therefore, the present invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device, comprising:
a substrate; and
a MISFET including source-drain regions formed in the substrate, a gate insulating film formed on the substrate, and a gate electrode formed on the gate insulating film ,the gate insulating film comprising a metal oxynitride film containing a metal-oxygen-nitrogen bond chain.

2. The semiconductor device according to claim 1, wherein the metal contained in the gate insulating film includes at least one element selected from the group consisting of Zr, Hf, Ti and a lanthanoide metal.

3. The semiconductor device according to claim 1, wherein the nitrogen concentration in the gate insulating film falls within a range of between 15 atomic % and 30 atomic %.

4. A semiconductor device, comprising:
a substrate; and
a MISFET including source-drain regions formed in the substrate, a gate insulating film on the substrate and a gate electrode formed on the gate insulating film, the gate insulating film comprising a nitrided metal silicate film containing one of a metal-oxygen-nitrogen bond chain and a silicon-oxygen nitrogen bond chain.

5. The semiconductor device according to claim 4, wherein the metal contained in the gate insulating film includes at least one element selected from the group consisting of Zr, Hf, Ti and a lanthanoide metal.

6. The semiconductor device according to claim 4, wherein the nitrogen concentration in the gate insulating film falls within a range of between 15 atomic % and 30 atomic %.

7. A method of manufacturing a semiconductor device, comprising:
forming a metal oxide film on a substrate;
applying a heat treatment to the metal oxide film under temperature falling within a range of between 700° C. and 900° C.;
adding nitrogen to the metal oxide film after the heat treatment by using nitrogen under an excited state so as to obtain a gate insulating film consisting of a metal oxynitride film containing a metal-oxygen-nitrogen bond chain; and
forming a gate electrode on the gate insulating film.

8. The method for manufacturing a semiconductor device according to claim 7, further comprising applying a heat treatment to the gate insulating film under an oxygen partial pressure of 1×10⁻³ Torr or less, before forming the gate electrode.

9. The method for manufacturing a semiconductor device according to claim 7, wherein forming the gate electrode is continuously carried out under vacuum after deposition of the gate insulating film without exposing the gate electrode to the air atmosphere.

10. The method for manufacturing a semiconductor device according to claim 7, wherein the metal contained in the gate insulating film includes at least one element selected from the group consisting of Zr, Hf, Ti and a lanthanoide metal.

11. A method of manufacturing a semiconductor device, comprising:
forming a metal silicate film on a substrate;
applying a heat treatment to the metal silicate film under temperature falling within a range of between 700° C. and 900° C.;
adding nitrogen to the metal silicate film after the heat treatment by using nitrogen under an excited state so as to obtain a gate insulating film consisting of a nitrided metal silicate film containing at least one of a metal-oxygen-nitrogen bond chain and a silicon-oxygen-nitrogen bond chain; and
forming a gate electrode on the gate insulating film.

12. The method for manufacturing a semiconductor device according to claim 11, further comprising applying a heat treatment to the gate insulating film under an oxygen partial pressure of 1×10⁻³ Torr or less before forming the gate electrode.

13. The method for manufacturing a semiconductor device according to claim 11, wherein forming the gate electrode is continuously carried out under vacuum after deposition of the gate insulating film without exposing the gate electrode to the air atmosphere.

14. The method for manufacturing a semiconductor device according to claim 11, wherein the metal contained in the gate insulating film includes at least one element selected from the group consisting of Zr, Hf, Ti and a lanthanoide metal.

15. A method of manufacturing a semiconductor device, comprising:
forming by a CVD method on a substrate a gate insulating film consisting of a metal oxynitride film having a metal-oxygen-nitrogen bond chain, the CVD method being carried out in the presence of nitrogen under an excited state; and
forming a gate electrode on the gate insulating film.

16. The method for manufacturing a semiconductor device according to claim 15, further comprising applying a heat treatment to the gate insulating film under an oxygen partial pressure of 1×10⁻³ Torr or less, before forming the gate electrode.

17. The method for manufacturing a semiconductor device according to claim 15, wherein forming the gate electrode is continuously carried out under vacuum after deposition of the gate insulating film without exposing the gate electrode to the air atmosphere.

18. The method for manufacturing a semiconductor device according to claim 15, wherein the metal contained in the gate insulating film includes at least one element selected from the group consisting of Zr, Hf, Ti and a lanthanoide metal.

19. A method of manufacturing a semiconductor device, comprising:
forming by a CVD method on a substrate a gate insulating film consisting of a nitrided metal silicate film having at least one of a metal-oxygen-nitrogen bond chain and a silicon-oxygen-nitrogen bond chain, the CVD method being carried out in the presence of nitrogen under an excited state; and
forming a gate electrode on the gate insulating film.

20. The method for manufacturing a semiconductor device according to claim 19, further comprising applying a heat treatment to the gate insulating film under an oxygen partial pressure of 1×10⁻³ Torr or more, before forming the gate electrode.

21. The method for manufacturing a semiconductor device according to claim 19, wherein forming the gate electrode is continuously carried out under vacuum after deposition of the gate insulating film without exposing the gate electrode to the air atmosphere.

22. The method for manufacturing a semiconductor device according to claim 19, wherein the metal contained in the gate insulating film includes at least one element selected from the group consisting of Zr, Hf, Ti and a lanthanoide metal.

23. A semiconductor device, comprising:
a substrate; and
a MISFET including source-drain regions formed in the substrate, a gate insulating film formed on the substrate, and a gate electrode formed on the gate insulating film , the gate insulating film comprising a metal oxynitride film, the metal oxynitride film consisting of metal, oxygen and nitrogen, and the metal oxynitride film having peaks of binding energy corresponding to a metal-oxygen bond and a oxygen-nitrogen bond.

24. A semiconductor device, comprising:
a substrate; and
a MISFET including source-drain regions formed in the substrate, a gate insulating film formed on the substrate, and a gate electrode formed on the gate insulating film, the gate insulating film comprising a nitride metal silicate film, the nitride metal silicate film consisting of metal, oxygen, nitrogen and silicon, and the nitride metal silicate film having peaks of binding energy corresponding to a oxygen-nitride bond and a silicon-nitrogen bond.
